(19) United States
(12) Patent Application Publication
(10) Pub. No.: US 2024/0321656 A1
(43) Pub. Date: Sep. 26, 2024

(54) GLASS CORE SUBSTRATE WITH LGA NOTCH

(71) Applicant: Intel Corporation, Santa Clara, CA (US)

(72) Inventors: Gang DUAN, Chandler, AZ (US); Aaron GARELICK, Chandler, AZ (US); Brandon C. MARIN, Gilbert, AZ (US); Srinivas V. PIETAMBARAM, Chandler, AZ (US)

(21) Appl. No.: 18/126,134

(22) Filed: Mar. 24, 2023

(51) Int. Cl. H01L 23/15; H01L 23/498

(52) U.S. Cl. CPC H01L 23/15; H01L 23/49816; H01L 23/49827; H01L 23/49838

(57) ABSTRACT

Embodiments disclosed herein include package substrates. In an embodiment, the package substrate comprises a core, where the core comprises glass, and an insert in the core. In an embodiment, the insert is a different material than the core. In an embodiment, a first layer is over the core and a second layer is under the core. In an embodiment, a notch is provided through the first layer, the core, and the second layer. In an embodiment, the notch passes through the insert in the core.

### TECHNICAL FIELD

Embodiments of the present disclosure relate to electronic systems, and more particularly to package substrates that include a glass core with a notch that includes a buffer through the glass core.

### BACKGROUND

In many land grid array (LGA) packages, one or more notches are fabricated along the edge of the package substrate. The notch provides a location for inserting a fastener that can be secured to the main board. The fastener may be a bolt, screw, or the like. The notch also provides proper alignment between the package substrate and the main board. Typically, the notch is formed into the package substrate after assembly through the use of a mechanical drill. In the case of traditional organic core structures, this mechanical drilling works relatively well.

However, in the case of package substrates with a glass core, the drilling process leads to reliability concerns. Particularly, during the mechanical drilling process, the drill bit may induce stress in the glass core. This ultimately may result in cracking or other damage to the glass core. A cracked glass core can result in a significant reliability issue and is desired to be avoided. In some instances, it has been shown that an approximate substrate yield approaches zero percent, meaning that all package substrates notched with a mechanical drilling process suffer significant crack propagation and core structure degradation.

### BRIEF DESCRIPTION OF THE DRAWINGS

FIG. 1A is a plan view illustration of a package substrate with several notches formed along the edge of the package substrate, in accordance with an embodiment.

FIG. 1B is a cross-sectional illustration of the package substrate in FIG. 1A along line B-B′, in accordance with an embodiment.

FIG. 2A is a plan view illustration of a package substrate with polymer inserts provided in the core around the notches, in accordance with an embodiment.

FIG. 2B is a cross-sectional illustration of the package substrate in FIG. 2A along line B-B′, in accordance with an embodiment.

FIG. 3A is a cross-sectional illustration of a package substrate with a polymer insert with tapered sidewalls in the core lining the notch, in accordance with an embodiment.

FIG. 3B is a cross-sectional illustration of a package substrate with a polymer insert with hourglass shaped sidewalls in the core lining the notch, in accordance with an embodiment.

FIG. 4A is a cross-sectional illustration of a glass core, in accordance with an embodiment.

FIG. 4B is a cross-sectional illustration of the glass core after a laser exposure process, in accordance with an embodiment.

FIG. 4C is a cross-sectional illustration of the glass core after the exposed region is removed, in accordance with an embodiment.

FIG. 4D is a cross-sectional illustration of the glass core after a polymer insert is provided in the opening in the glass core, in accordance with an embodiment.

FIG. 4E is a cross-sectional illustration of a package substrate that includes the glass core with the polymer insert, in accordance with an embodiment.

FIG. 4F is a cross-sectional illustration of the package substrate after a notch that passes through the polymer insert is formed through the package substrate, in accordance with an embodiment.

FIG. 5A is a plan view illustration of a package substrate with rectangular notches along the edges of the package substrate, in accordance with an embodiment.

FIG. 5B is a plan view illustration of a package substrate with triangular notches along the edges of the package substrate, in accordance with an embodiment.

FIG. 6 is a cross-sectional illustration of an electronic system that comprises a package substrate with a notch that passes through a polymer insert in the glass core of the package substrate, in accordance with an embodiment.

FIG. 7 is a schematic of a computing device built in accordance with an embodiment.

### EMBODIMENTS OF THE PRESENT DISCLOSURE

Described herein are electronic systems, and more particularly package substrates that include a glass core with a notch that includes a buffer through the glass core, in accordance with various embodiments. In the following description, various aspects of the illustrative implementations will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative implementations. However, it will be apparent to one skilled in the art that the present invention may be practiced without the specific details. In other instances, well-known features are omitted or simplified in order not to obscure the illustrative implementations.

Various operations will be described as multiple discrete operations, in turn, in a manner that is most helpful in understanding the present invention, however, the order of description should not be construed to imply that these operations are necessarily order dependent. In particular, these operations need not be performed in the order of presentation.

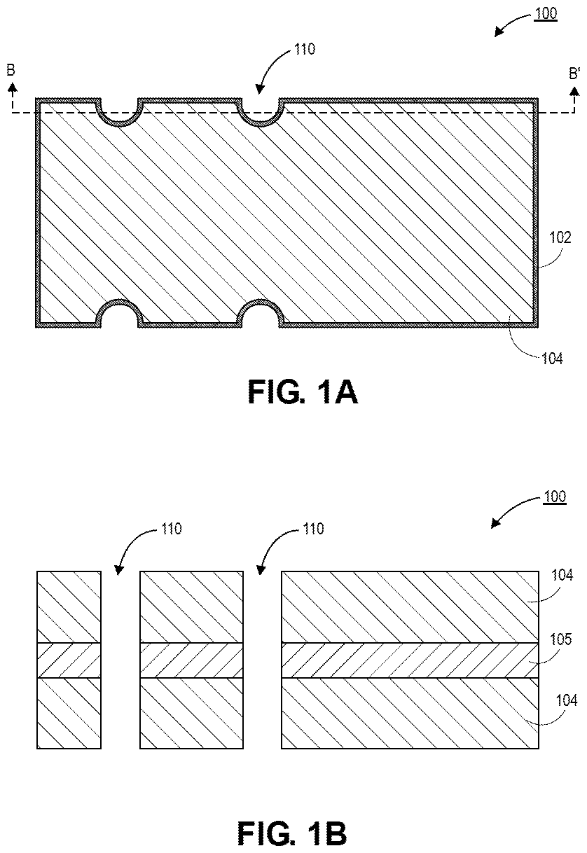

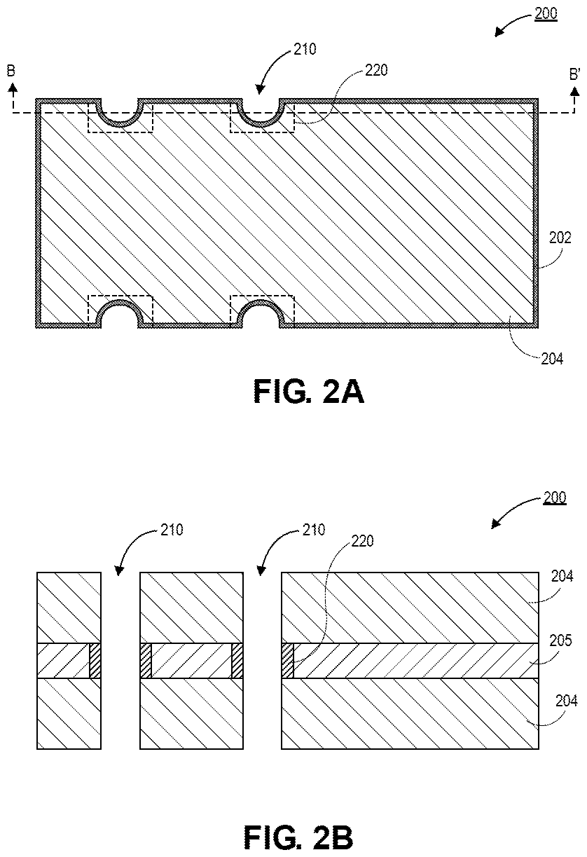

As noted above, land grid array (LGA) packages may include notches in order to accommodate fasteners (e.g., bolts, screws, etc.) that secure the package to the board. The notches are typically formed along edges of the package substrate. One example of such a package substrate 100 is shown in the plan view illustration of FIG. 1A. As shown, a buildup layer 104 may be the top layer. Though, in other instances, a solder resist or the like may be provided as the top layer. Additionally, conductive pads, traces, and the like may also be provided over the top layer, but are omitted here for simplicity and ease of understanding of embodiments disclosed herein. A metal free ring 102 may also be provided around a perimeter of the package substrate 100.

As shown, one or more notches 110 may be provided through the package substrate 100. For example, four notches 110 are shown in FIG. 1A. The notches 110 may pass through an entire thickness of the package substrate 100. That is, the notches 110 may pass through buildup layers that are provided both above and below a core. In the case of an organic core, the drilling process (e.g., a mechanical drilling process), will not significantly damage the package substrate 100.

However, in the case of a glass core package substrate, a mechanical drilling process may result in damage to the core. A cross-sectional illustration of the package substrate 100 along line B-B′ in FIG. 1A is shown in FIG. 1B. As shown, the buildup layers 104 are provided above and below a core 105. In the case of a glass core 105, the drilling process to form the notches 110 may result in the formation of cracking or other damage to the core 105. As such, alternative methods of forming the notches may be needed in order to provide high yielding package substrates 100.

Accordingly, embodiments disclosed herein may include package substrates that include modified glass cores. The bulk of the core may remain glass, but proximate to the location of the notch. The polymer insert may be inserted into a hole that is fabricated into the glass core before the buildup layers are formed. For example, a laser assisted etching process may be used instead of a mechanical drilling process. The laser assisted etching process (described in greater detail below) allows for a hole to be formed into the glass core without significant damage to the structure of the glass core. Then, when the notch is formed through the entirety of the package substrate, the mechanical drill will only pass through the polymer insert instead of the glass material of the core. As such, notches can be fabricated without damaging the glass core, and yields are significantly improved.

Referring now to FIG. 2A, a plan view illustration of a package substrate 200 is shown, in accordance with an embodiment. In an embodiment, the package substrate comprises multiple layers, such as a core and buildup layers 204 provided over the core. The top buildup layer 204 is shown in FIG. 2A. Though, it is to be appreciated that a solder resist or the like may also be provided over the buildup layer 204. In the illustrated embodiment, there are no conductive features (e.g., pads, traces, etc.) on the top buildup layer 204 for simplicity. It is to be appreciated that embodiments may include pads or traces on the top buildup layer 204. A ring of a metal free region 202 may be provided around a perimeter of the package substrate 200.

In an embodiment, one or more notches 210 may be provided along edges of the package substrate 200. The notches 210 may be circular shaped, as shown in FIG. 2A. Though, the notches 210 may be other shapes, as will be described in greater detail below. The notches 210 may have a dimension (e.g., diameter) that is up to approximately 5 mm. In a particular embodiment, the dimension of the notches 210 may be between approximately 0.25 mm and approximately 2 mm. As used herein, “approximately” may refer to a range of values that is within ten percent of the stated value. For example, approximately 5 mm may refer to a range between 4.5 mm and 5.5 mm.

In the illustrated embodiment, a set of four notches 210 is shown. Though, embodiments may include any number of notches 210 (e.g., one or more notches 210). The notches 210 are shown as being along two opposite edges of the package substrate 200. In other embodiments, the notches 210 may be along a single edge, two edges, three edges, or four edges of the package substrate 200.

In an embodiment, an insert 220 may be provided within the package substrate around the notch 210. The insert 220 is shown with dashed lines to indicate that the insert is provided below the top surface of the package substrate 200. For example, the insert 220 may be provided in a core layer of the package substrate 200. As such, when the notches 210 are drilled, the drill bit does not pass through the core itself. Instead, the drill bit passes through the insert 220, which is more resistant to damage than the core. The insert 220 may be a polymer insert 220 in some embodiments.

In an embodiment, the insert 220 may have a rectangular shape when viewed from above. Further, since the insert 220 is provided at the edge of the package substrate 200, the insert 220 may form a U-shape around the notch 210. That is, the insert 220 may be provided around at least three sides of the notch 210, with the fourth side being open.

Referring now to FIG. 2B, a cross-sectional illustration of the package substrate 200 in FIG. 2A along line B-B′ is shown, in accordance with an embodiment. As shown, the package substrate 200 may comprise a core 205 between buildup layers 204. The core 205 may comprise glass. More particularly, the core 205 may comprise substantially all glass. That is, the core 205 is different than an organic core that may include glass fiber reinforcement. The core 205 may comprise a glass formulation that is compatible with laser assisted etching process. Laser assisted etching processes will be described in greater detail below. For example, the core 205 may comprise a borosilicate glass, a fused silica glass, or any other suitable glass formulation. In an embodiment, the core 205 may have a thickness up to approximately 1,000 μm. For example, the core 205 may have a thickness between approximately 50 μm and approximately 500 μm. Since the core 205 comprises substantially all glass, the core is susceptible to damage during mechanical drilling used to form the notches 210.

In an embodiment, the buildup layers 204 are shown as a single layer above and below the core 205. Though, it is to be appreciated that multiple buildup layers may be laminated over each other both above and below the core 205. While conductive features (e.g., pads, traces, vias) are omitted for simplicity, it is to be appreciated that the conductive features typical of package substrates may be provided in the package substrate 200.

In an embodiment, notches 210 may be provided through the buildup layers 204 and the core 205. The notches 210 may have substantially vertical sidewalls due to the mechanical drilling process. As the notches 210 pass through the core 205, the notches 210 may be lined with an insert 220. The insert 220 may form a partial ring around the notch 210 through the thickness of the core 205. That is, the insert 220 may wrap around the backside of the notch 210. The insert 220 may directly contact the core 205.

In an embodiment, the insert 220 may comprise a polymer material. The polymer material may be easier to drill through than the glass of the core 205. As the notch 210 is formed through the insert 220, the glass core 205 is protected so that the glass core 205 does not crack. In some embodiments, the insert 220 comprises a coefficient of thermal expansion (CTE) that is substantially equal to a CTE of the glass core 205. For example, the value of the CTE of the insert 220 may be within ten percent of the value of the CTE of the core 205. As such, thermal cycling does not add additional stress to the core 205.

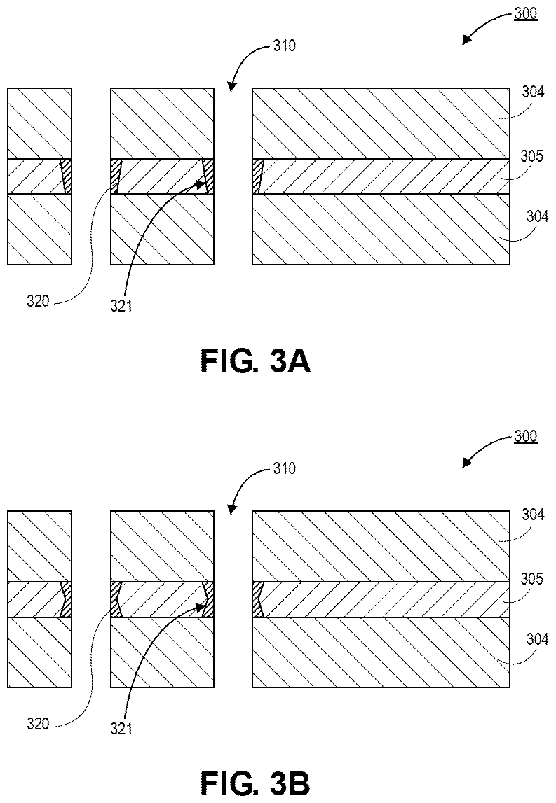

Referring now to FIG. 3A, a cross-sectional illustration of a package substrate 300 is shown, in accordance with an additional embodiment. The package substrate 300 may comprise a core 305 that comprises a glass formulation. The core 305 may have a thickness up to approximately 1,000 μm. For example, the core 305 may have a thickness between approximately 50 μm and approximately 500 μm. The core 305 may have a glass formulation such as a borosilicate glass or a fused silica glass.

In an embodiment, buildup layers 304 may be provided above and below the core 305. The buildup layers 304 may be organic buildup film. While not shown for simplicity, the buildup layers 304 may further comprise conductive features (e.g., pads, traces, vias, etc.). The buildup layers 304 are shown as a single layer each. But it is to be appreciated that each of the buildup layers 304 may comprise a plurality of laminated layers. In some embodiments, vias (not shown) through the core 305 may couple routing in the bottom buildup layer 304 to routing in the top buildup layer 304.

In an embodiment, one or more notches 310 may be provided through the package substrate 300. The notches 310 may have substantially vertical sidewalls. This is attributable to the notch 310 forming process using a mechanical drilling process. As the notch 310 passes through the core 305, the notch 310 is lined by an insert 320. The insert 320 may be a different material than the core 305. For example, the insert 320 may be a polymer or the like. The insert 320 may have a CTE that is within ten percent of the CTE of the core 305 in some embodiments.

In an embodiment, the insert 320 may have sidewalls 321 that are tapered or otherwise non-vertical. For example, the plane of the sidewalls 321 may intersect the plane of the sidewall of the notch 310. More generally, the sidewalls 321 are not parallel to the sidewalls of the notches 310. The taper shown in FIG. 3A is one where the width of the insert 320 decreases through a thickness of the insert 320. For example, a top of the insert 320 is wider than a bottom of the insert 320.

The tapered sidewall 321 of the insert 320 may be attributable to the processing used to form the insert 320. For example, a laser assisted etching process may be used to form a cavity in the core 305. The laser assisted etching process may result in a cavity that has the tapered sidewalls. Then, when the insert 320 is inserted into the core 305, the insert 320 will conform to the cavity and result in tapered sidewalls 321.

In an embodiment, the insert 320 prevents damage to the core 305 during the notch 310 forming process. Instead of the mechanical drill bit passing through the core 305 (which may cause cracking or other damage), the mechanical drill bit passes through the insert 320. The insert 320 may be a material that is softer than the core 305 and allows for stresses to be absorbed without transferring the stress to the core 305.

Referring now to FIG. 3B, a cross-sectional illustration of a package substrate 300 is shown, in accordance with an additional embodiment. The package substrate 300 in FIG. 3B may be substantially similar to the package substrate 300 in FIG. 3A, with the exception of the shape of the sidewalls 321 of the insert 320. Instead of having a single taper, the sidewalls 321 result in the formation of an hourglass-shaped insert 320. That is, the top and bottom of the insert 320 are wider than a middle region of the insert 320.

An hourglass shaped cross-section for the insert 320 may be formed through the use of dual sided laser assisted etching process. In such an embodiment, laser exposure of the core 305 is provided from both above and below the core. After the etching process, a cavity with an hourglass shape is formed. The insert 320 then conforms to the shape of the cavity to result in the double tapered hourglass shape.

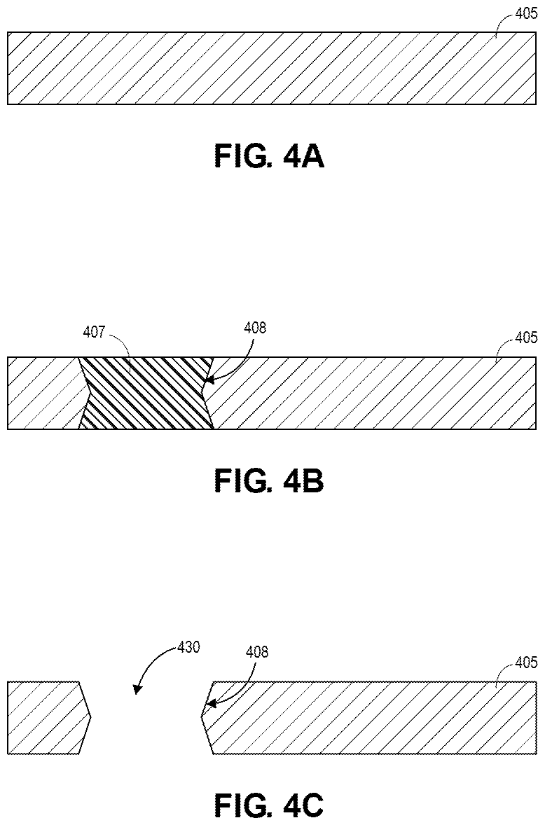

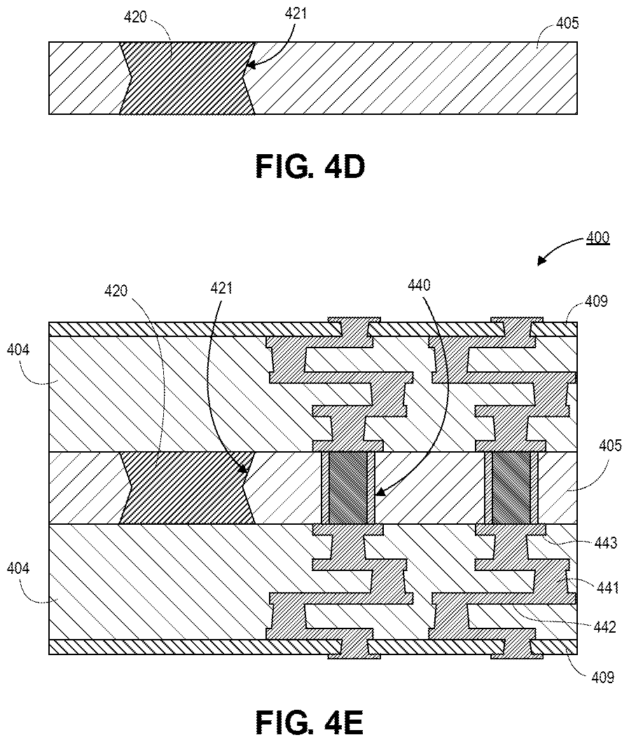

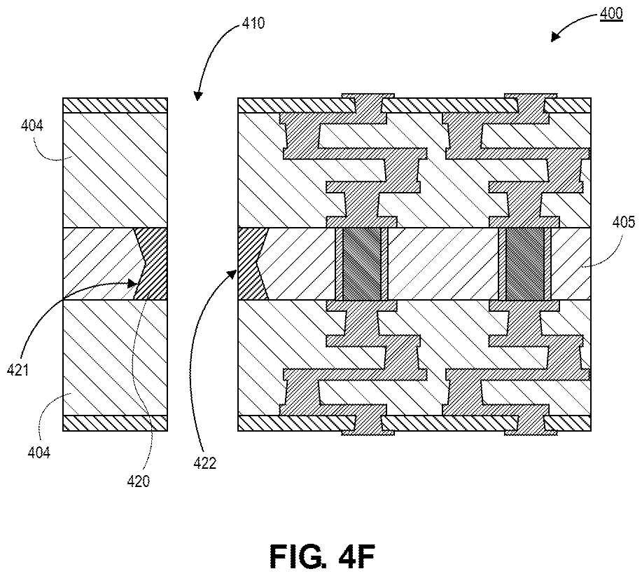

Referring now to FIGS. 4A-4F, a series of cross-sectional illustrations depicting a process for forming a package substrate with notches is shown, in accordance with an embodiment. In an embodiment, the package substrate comprises a glass core. The glass core includes an insert, and the notch passes through the insert instead of the glass core. As such, damage to the core caused during notch drilling is minimized.

Referring now to FIG. 4A, a cross-sectional illustration of a core 405 is shown, in accordance with an embodiment. In an embodiment, the core 405 may comprise substantially all glass. The glass formulation may be one that is compatible with laser assisted etching processes. For example, the core 405 may comprise borosilicate glass, fused silica glass, or the like. In an embodiment, the core 405 may have any suitable thickness for the core 405 of a package substrate. In one embodiment, the core 405 may have a thickness up to approximately 1,000 μm. Though, thicker cores 405 may also be used in some embodiments. In an embodiment, the core 405 may have a thickness between approximately 50 μm and approximately 500 μm. In an embodiment, the core 405 may be part of a panel. That is, a plurality of different package substrates may be fabricated in parallel. However, only a portion of one of the package substrates is shown in the embodiments shown in FIGS. 4A-4F.

Referring now to FIG. 4B, a cross-sectional illustration of the core 405 after a laser exposure is shown, in accordance with an embodiment. The laser exposure may result in the formation of a modified region 407. The modified region 407 may have a microstructure or phase that is different than that of the remainder of the core 405. In an embodiment, the sidewall 408 of the modified region 407 may be tapered. For example, the embodiment shown in FIG. 4B has sidewalls 408 that result in the formation of an hourglass shaped modified region 407. Such an embodiment may be the result of a dual sided laser exposure process. In a dual sided exposure, a laser is used over both the top surface and the bottom surface of the core 405.

Referring now to FIG. 4C, a cross-sectional illustration of the core 405 after an etching process is shown, in accordance with an embodiment. In an embodiment, the etching process may selectively remove the modified region 407 to form a cavity 430. The cavity 430 may have sidewalls 408 that are double tapered to form an hourglass shaped cavity 430. In an embodiment, the cavity 430 may be provided at the edge of the core 405. From a top view, the cavity 430 may be circular shape into the edge of the core 405. Though, as will be described in greater detail below, the cavity 430 may have any suitable shape.

Referring now to FIG. 4D, a cross-sectional illustration of the core 405 after an insert 420 is provided in the cavity 430 is shown, in accordance with an embodiment. In an embodiment, the insert 420 comprises a material that is different than the material of the core 405. In one embodiment, the insert 420 comprises a polymer material or another material that is softer than the core 405. As such, during a subsequent notch forming process, the drill passes through the insert 420 instead of being formed through the core 405.

In an embodiment, the insert 420 may be inserted into the cavity using any suitable deposition process. In some embodiments, excess insert 420 material may be disposed over the top and/or bottom surface of the core 405. In such embodiments, the excess material may be removed with an etching or polishing process. Accordingly, the top surface of the insert 420 is substantially coplanar with a top surface of the core 405, and a bottom surface of the insert 420 is substantially coplanar with a bottom surface of the core 405. The deposition process for the insert 420 may be a molding process, an injection process, a printing process, or the like.

In an embodiment, the insert 420 conforms to the shape of the cavity 430. As such, the sidewalls 421 of the insert 420 may also be tapered in some embodiments. For example, in the embodiment shown in FIG. 4D, the insert 420 comprises an hourglass shaped cross-section. Though, embodiments may include a single taper, or substantially no taper, depending on the processes used to form the cavity 430.

Referring now to FIG. 4E, a cross-sectional illustration of a package substrate 400 is shown, in accordance with an embodiment. The package substrate 400 may be fabricated on the core 405. In one embodiment, through glass vias (TGVs) 440 may be provided through the core 405. In the illustrated embodiment, the TGVs 440 are conductive shells around a core. Though, in other embodiments, the core may be omitted, and the TGVs 440 may be a solid conductive feature. The TGVs 440 may be formed before, after, or during the formation of the insert 420.

In an embodiment, buildup layers 404 may be provided above and below the core 405. The buildup layers 404 may comprise a plurality of laminated organic buildup layers. Additionally, conductive routing (e.g., pads 443, traces 442, and vias 441) may be fabricated within the buildup layers 404. The conductive routing may be formed with standard package assembly processes, such as semi-additive patterning (SAP) or the like. In an embodiment, the conductive routing in the top buildup layers 404 may be electrically coupled to the conductive routing in the bottom buildup layers 404 through the TGVs 440. In some embodiments, solder resist 409 may also be provided over the top and/or the bottom of the package substrate 400.

It is to be appreciated that the structure shown in FIG. 4E, is exemplary and may not represent the true placement of various components. For example, the insert 420 may be provided at the edge of the package substrate 400, and the TGVs 440 and associated routing in the buildup layers 404 may be provided towards the center of the package substrate 400. That is, a cross-section that shows an insert 420, such as the insert shown in FIG. 4E, may not also include TGVs 440 in some embodiments.

In an embodiment, a voided region may be provided above and below the insert 420. As used herein, a voided region may be a region of the buildup layers 404 that is substantially free from metal or other conductive routing. The voided region allows for the mechanical drilling to pass through only the buildup film of the buildup layers 404 and the insert 420.

Referring now to FIG. 4F, a cross-sectional illustration of the package substrate 400 after the notch 410 is formed is shown, in accordance with an embodiment. The notch 410 may have substantially vertical sidewalls as a result of a mechanical drilling process. The notch 410 may pass through the buildup layers 404 and the insert 420.

In some embodiments, the notch 410 formation process results in an insert 420 that has an outer sidewall 421 and an inner sidewall 422. The outer sidewall 421 may be non-parallel with the inner sidewall 422. For example, the inner sidewall 422 (which is formed by the mechanical drilling process) may be vertical, and the outer sidewall 421 (which is formed by the laser assisted etching process) may be tapered. In the particular embodiment shown in FIG. 4F, the tapered outer sidewall 421 is a double tapered sidewall that forms an hourglass shaped insert 420. Though, it is to be appreciated that a single taper outer sidewall 421 may also be provided in some embodiments.

In an embodiment, the insert 420 forms a U-shape around the notch 410. For example, the two portions of the insert 420 shown in FIG. 4F cover two sides of the notch 410. The two portions of the insert 420 may be connected to each other in a plane into the page of FIG. 4F. As such, at least three sides of the notch 410 are lined by the insert 420. The fourth side (out of the plane of the page of FIG. 4F) may be uncovered by either the insert 420 or the core 405.

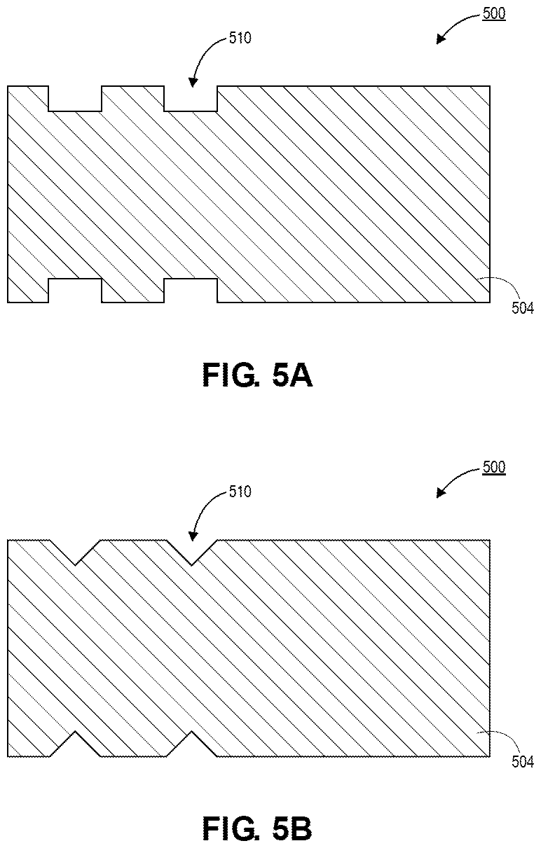

Referring now to FIGS. 5A and 5B, plan view illustrations of package substrates 500 are shown, in accordance with various embodiments. The package substrates 500 may have similar structures to those described in greater detail above, with the exception of the shape of the notches 510. For example, the package substrates 500 may comprise a core (not shown) and buildup layers 504 over and under the core. In an embodiment, inserts may be provided in the core around the notches 510. The inserts may be U-shaped in some embodiments, similar to the embodiment shown in FIG. 2A.

Referring now to FIG. 5A, the package substrate 500 is shown with notches 510 that have substantially rectangular shapes. In FIG. 5B, the notches 510 have substantially triangular shapes. While examples disclosed herein include circular notches, rectangular notches, or triangular notches, it is to be appreciated that any notch shape may be used in accordance with embodiments disclosed herein.

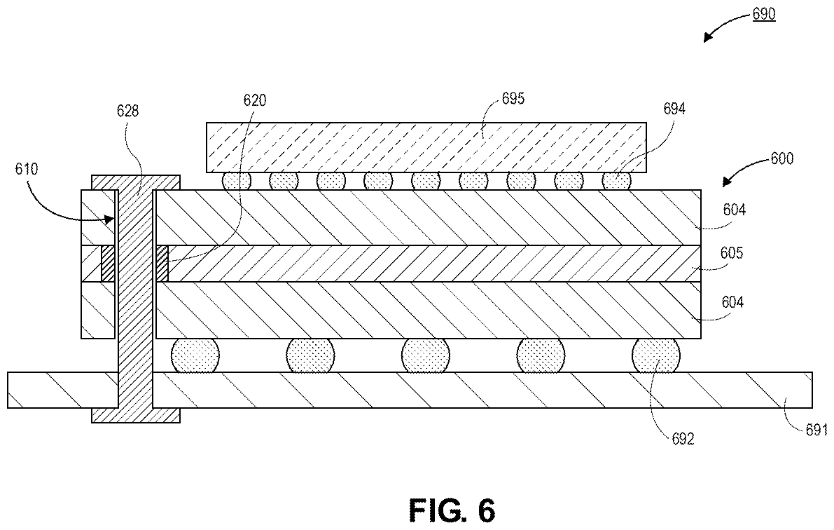

Referring now to FIG. 6, a cross-sectional illustration of an electronic system 690 is shown, in accordance with an embodiment. In an embodiment, the electronic system 690 may comprise a board 691, such as a printed circuit board (PCB) or the like. The board 691 may be coupled to a package substrate 600 through interconnects 692. The interconnects 692 may be solder balls, sockets, or any other suitable interconnect architecture. In a particular embodiment, the interconnects 692 are used for an LGA package substrate 600.

In an embodiment, the package substrate 600 comprises a core 605 and buildup layers 604 over and under the core 605. In a particular embodiment, the core 605 is a glass core. In an embodiment, a notch 610 is provided through a thickness of the package substrate 600. The notch 610 may be provided at the edge of the package substrate 600. The notch 610 may pass through the buildup layers 604 and the core 605. However, the portion of the notch 610 that passes through the core 605 may be lined by an insert 620. The insert 620 may be a polymer in some embodiments. As such, the mechanical drilling process to form the notch 610 does not need to pass through the glass material of the core 605. The insert 620 may be similar to any of the inserts described in greater detail above. In an embodiment, a fastener 628 may pass through the notch 610 in order to mechanically couple and align the package substrate 600 to the board 691. The fastener 628 may be a bolt, a screw, or the like.

In an embodiment, one or more dies 695 may be coupled to the package substrate 600 by interconnects 694. The interconnects 694 may be solder balls, copper bumps, or any other first level interconnect (FLI) architecture. The one or more dies 695 may be compute dies, such as a central processing unit (CPU), a graphics processing unit (GPU), an XPU, a system on a chip (SoC), a communications die, or a memory die.

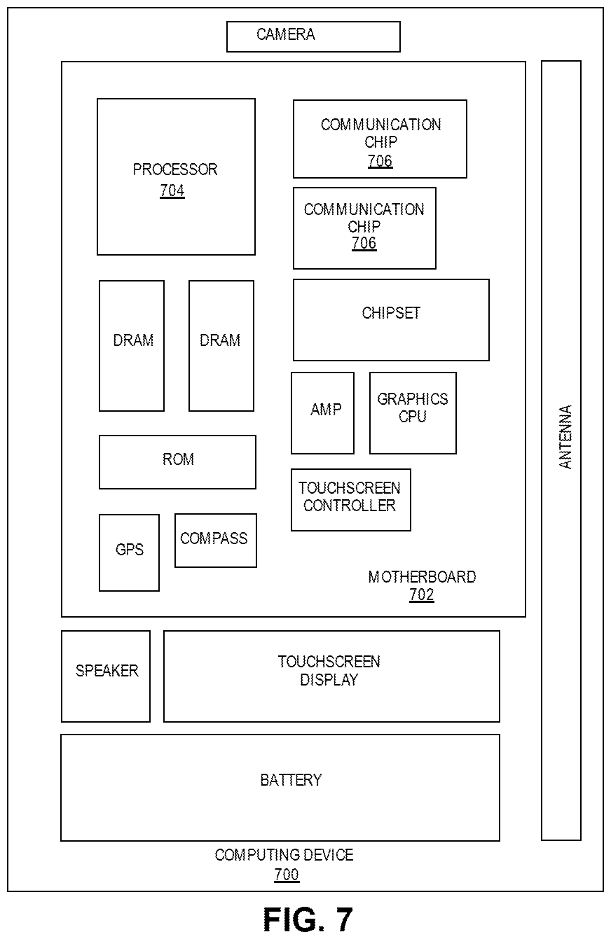

FIG. 7 illustrates a computing device 700 in accordance with one implementation of the invention. The computing device 700 houses a board 702. The board 702 may include a number of components, including but not limited to a processor 704 and at least one communication chip 706. The processor 704 is physically and electrically coupled to the board 702. In some implementations the at least one communication chip 706 is also physically and electrically coupled to the board 702. In further implementations, the communication chip 706 is part of the processor 704.

These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 706 enables wireless communications for the transfer of data to and from the computing device 700. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not. The communication chip 706 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 700 may include a plurality of communication chips 706. For instance, a first communication chip 706 may be dedicated to shorter range wireless communications such as Wi-Fi and Bluetooth and a second communication chip 706 may be dedicated to longer range wireless communications such as GPS, EDGE, GPRS, CDMA, WiMAX, LTE, Ev-DO, and others.

The processor 704 of the computing device 700 includes an integrated circuit die packaged within the processor 704. In some implementations of the invention, the integrated circuit die of the processor may be part of an electronic package with a notch that passes through the package substrate, and where an insert is provided in a core around the notch, in accordance with embodiments described herein. The term “processor” may refer to any device or portion of a device that processes electronic data from registers and/or memory to transform that electronic data into other electronic data that may be stored in registers and/or memory.

The communication chip 706 also includes an integrated circuit die packaged within the communication chip 706. In accordance with another implementation of the invention, the integrated circuit die of the communication chip may be part of an electronic package with a notch that passes through the package substrate, and where an insert is provided in a core around the notch, in accordance with embodiments described herein.

In an embodiment, the computing device 700 may be part of any apparatus. For example, the computing device may be part of a personal computer, a server, a mobile device, a tablet, an automobile, or the like. That is, the computing device 700 is not limited to being used for any particular type of system, and the computing device 700 may be included in any apparatus that may benefit from computing functionality.

The above description of illustrated implementations of the invention, including what is described in the Abstract, is not intended to be exhaustive or to limit the invention to the precise forms disclosed. While specific implementations of, and examples for, the invention are described herein for illustrative purposes, various equivalent modifications are possible within the scope of the invention, as those skilled in the relevant art will recognize.

These modifications may be made to the invention in light of the above detailed description. The terms used in the following claims should not be construed to limit the invention to the specific implementations disclosed in the specification and the claims. Rather, the scope of the invention is to be determined entirely by the following claims, which are to be construed in accordance with established doctrines of claim interpretation.

Example 1: a package substrate, comprising: a core, wherein the core comprises glass; an insert in the core, wherein the insert is a different material than the core; a first layer over the core; a second layer under the core; and a notch through the first layer, the core, and the second layer, wherein the notch passes through the insert in the core.

Example 2: the package substrate of Example 1, wherein the notch has substantially vertical sidewalls.

Example 3: the package substrate of Example 1 or Example 2, wherein the insert has substantially vertical sidewalls.

Example 4: the package substrate of Example 1 or Example 2, wherein the insert has tapered sidewalls.

Example 5: the package substrate of Example 4, wherein the tapered sidewalls form an hourglass shaped insert.

Example 6: the package substrate of Examples 1-5, wherein the insert comprises a polymer.

Example 7: the package substrate of Example 6, wherein the polymer has a coefficient of thermal expansion (CTE) that is within ten percent of a CTE of the core.

Example 8: the package substrate of Examples 1-7, wherein the notch is at an edge of the package substrate.

Example 9: the package substrate of Examples 1-8, wherein the notch has a diameter that is up to approximately 5 mm.

Example 10: the package substrate of Examples 1-11, wherein the first layer and the second layer comprise organic buildup films, and wherein conductive routing is provided in the first layer and the second layer.

Example 11: a package substrate, comprising: a glass core; buildup layers over and under the glass core; and a notch that passes through the buildup layers and the glass core, wherein the portion of the notch that passes through the glass core is lined by a polymer.

Example 12: the package substrate of Example 11, wherein the notch has vertical sidewalls.

Example 13: the package substrate of Example 11 or Example 12, wherein the polymer has tapered sidewalls.

Example 14: the package substrate of Examples 11-13, wherein the polymer has a coefficient of thermal expansion (CTE) that is within ten percent of a CTE of the glass core.

Example 15: the package substrate of Examples 11-14, wherein the notch has a diameter up to approximately 5 mm.

Example 16: the package substrate of Examples 11-15, wherein the notch is at an edge of the package substrate.

Example 17: the package substrate of Examples 11-16, wherein the notch is a partial circle, a rectangle, or a triangle.

Example 18: an electronic system, comprising: a board; a package substrate coupled to the board, wherein a notch passes through the package substrate, and wherein a portion of the notch passing through a glass core of the package substrate is lined by a polymer, and a die coupled to the package substrate.

Example 19: the electronic system of Example 18, further comprising: an attachment device passing through the notch and coupled to the board.

Example 20: the electronic system of Example 18 or Example 19, wherein the electronic system is part of a personal computer, a server, a mobile device, a tablet, or an automobile.

What is claimed is:

1. A package substrate, comprising:
a core, wherein the core comprises glass;
an insert in the core, wherein the insert is a different material than the core;
a first layer over the core;
a second layer under the core; and
a notch through the first layer, the core, and the second layer, wherein the notch passes through the insert in the core.

2. The package substrate of claim 1, wherein the notch has substantially vertical sidewalls.

3. The package substrate of claim 1, wherein the insert has substantially vertical sidewalls.

4. The package substrate of claim 1, wherein the insert has tapered sidewalls.

5. The package substrate of claim 4, wherein the tapered sidewalls form an hourglass shaped insert.

6. The package substrate of claim 1, wherein the insert comprises a polymer.

7. The package substrate of claim 6, wherein the polymer has a coefficient of thermal expansion (CTE) that is within ten percent of a CTE of the core.

8. The package substrate of claim 1, wherein the notch is at an edge of the package substrate.

9. The package substrate of claim 1, wherein the notch has a diameter that is up to approximately 5 mm.

10. The package substrate of claim 1, wherein the first layer and the second layer comprise organic buildup films, and wherein conductive routing is provided in the first layer and the second layer.

11. A package substrate, comprising:
a glass core;
buildup layers over and under the glass core; and
a notch that passes through the buildup layers and the glass core, wherein the portion of the notch that passes through the glass core is lined by a polymer.

12. The package substrate of claim 11, wherein the notch has vertical sidewalls.

13. The package substrate of claim 11, wherein the polymer has tapered sidewalls.

14. The package substrate of claim 11, wherein the polymer has a coefficient of thermal expansion (CTE) that is within ten percent of a CTE of the glass core.

15. The package substrate of claim 11, wherein the notch has a diameter up to approximately 5 mm.

16. The package substrate of claim 11, wherein the notch is at an edge of the package substrate.

17. The package substrate of claim 11, wherein the notch is a partial circle, a rectangle, or a triangle.

18. An electronic system, comprising:
a board;
a package substrate coupled to the board, wherein a notch passes through the package substrate, and wherein a portion of the notch passing through a glass core of the package substrate is lined by a polymer; and
a die coupled to the package substrate.

19. The electronic system of claim 18, further comprising:
an attachment device passing through the notch and coupled to the board.

20. The electronic system of claim 18, wherein the electronic system is part of a personal computer, a server, a mobile device, a tablet, or an automobile.
